(19) United States
(12) Patent Application Publication
(10) Pub. No.: US 2024/0203796 A1
(43) Pub. Date: Jun. 20, 2024

(54) METHOD FOR MANUFACTURING SEMICONDUCTOR DEVICE

(71) Applicant: SAMSUNG ELECTRONICS CO., LTD., Suwon-si (KR)

(72) Inventors: Byeong Seon PARK, Suwon-si (KR); Sang-Ho Yun, Suwon-si (KR); Woo Jin Jung, Suwon-si (KR)

(21) Appl. No.: 18/508,566

(22) Filed: Nov. 14, 2023

(30) Foreign Application Priority Data
Dec. 14, 2022 (KR) 10-2022-0174542

(51) Int. Cl. H01L 21/66; G03F 1/42; G03F 7/00; G03F 9/00; H01L 21/027

(52) U.S. Cl. CPC H01L 22/12; G03F 1/42; G03F 7/70633; G03F 7/706845; G03F 9/7065; H01L 21/027

(57) ABSTRACT

A method for manufacturing a semiconductor device, the method including forming a stack on a wafer, wherein the stack includes a plurality of layers of the stack, forming a photoresist pattern on the stack, determining whether a material of at least one layer among the plurality of layers of the stack has changed and whether at least one process among a plurality of processes for forming the plurality of layers of the stack has changed, changing a first wavelength for overlay measurement upon determination that the material of the at least one layer or the at least one process has changed, and measuring an overlay using the changed first wavelength for overlay measurement.

### CROSS-REFERENCE TO RELATED APPLICATION

Korean Patent Application No. 10-2022-0174542, filed on Dec. 14, 2022, in the Korean Intellectual Property Office, is incorporated by reference herein in its entirety.

### BACKGROUND

### 1. Field

A method for manufacturing a semiconductor device is disclosed.

### 2. Description of Related Art

In order to manufacture a semiconductor device, various semiconductor processes are performed on a wafer made of a semiconductor material.

### SUMMARY

Embodiments are directed to a method for manufacturing a semiconductor device, the method including forming a stack on a wafer, wherein the stack includes a plurality of layers of the stack, forming a photoresist pattern on the stack, determining whether a material of at least one layer among the plurality of layers of the stack has changed and whether at least one process among a plurality of processes for forming the plurality of layers of the stack has changed, changing a first wavelength for overlay measurement upon determination that the material of the at least one layer or the at least one process has changed, and measuring an overlay using the changed first wavelength for overlay measurement.

Embodiments are directed to a method for manufacturing a semiconductor device, the method including forming a stack on a wafer, wherein the stack includes a plurality of layers of the stack, forming a photoresist pattern on the stack, determining whether a material of at least one layer among the plurality of layers of the stack has changed and whether at least one process among a plurality of processes for forming the plurality of layers of the stack has changed, changing a first wavelength for alignment upon determination that the material of the at least one layer or the at least one process has changed, aligning the wafer using the changed first wavelength for alignment, and developing the photoresist to generate a photoresist pattern.

Embodiments are directed to a method for manufacturing a semiconductor device, the method including forming a stack on a wafer, wherein the stack includes a plurality of layers of the stack, forming a photoresist pattern on the stack, aligning the wafer, and then developing the photoresist to generate a photoresist pattern, determining whether a material of at least one layer of the plurality of layers of the stack has changed and whether at least one process among a plurality of process for forming the plurality of layers of the stack has changed, changing a measurement wavelength upon determination that the material of the at least one layer or the at least one process has changed, and aligning the wafer and/or measuring an overlay of the photoresist pattern is performed using the changed measurement wavelength.

### BRIEF DESCRIPTION OF DRAWINGS

Features will become apparent to those of skill in the art by describing in detail exemplary embodiments with reference to the attached drawings in which:

FIG. 1 is a schematic cross-sectional view showing an example embodiment of a lithographic apparatus.

FIG. 2 is a schematic plan view showing an example embodiment of a lithography cell or cluster.

FIG. 3 is a flowchart showing steps in a method for manufacturing a semiconductor device according to example embodiments.

FIG. 4 is a diagram showing a wafer according to example embodiments.

FIG. 5 is an enlarged view showing a shot area in FIG. 4.

FIG. 6 is a cross-sectional view showing a method for manufacturing a semiconductor device according to example embodiments.

FIG. 7 is a flowchart showing steps in a method for manufacturing a semiconductor device according to example embodiments.

FIG. 8 is a graph showing wavelength-based stack sensitivities.

FIG. 9 is a graph calculating a coefficient of determination based on comparing stack sensitivities A and B.

FIG. 10 is a graph calculating a coefficient of determination based on comparing stack sensitivities A and C.

FIG. 11 is a graph showing a position error based on a deformation amount.

FIG. 12 shows a profile of the first or second overlay mark without deformation.

FIG. 13 shows a profile of the first or second overlay mark with deformation.

FIG. 14 shows a table having a first to fourth asymmetry index.

FIG. 15 is a diagram showing first and second overlay marks of FIG. 6.

FIG. 16 is a flowchart showing steps in a method for manufacturing a semiconductor device according to example embodiments.

FIG. 17 is a flowchart showing steps in a method for manufacturing a semiconductor device according to example embodiments.

FIG. 18 is a flowchart showing steps included in S20 in FIG. 17.

FIG. 19 is a flowchart showing steps in a method for manufacturing a semiconductor device according to example embodiments.

### DETAILED DESCRIPTION

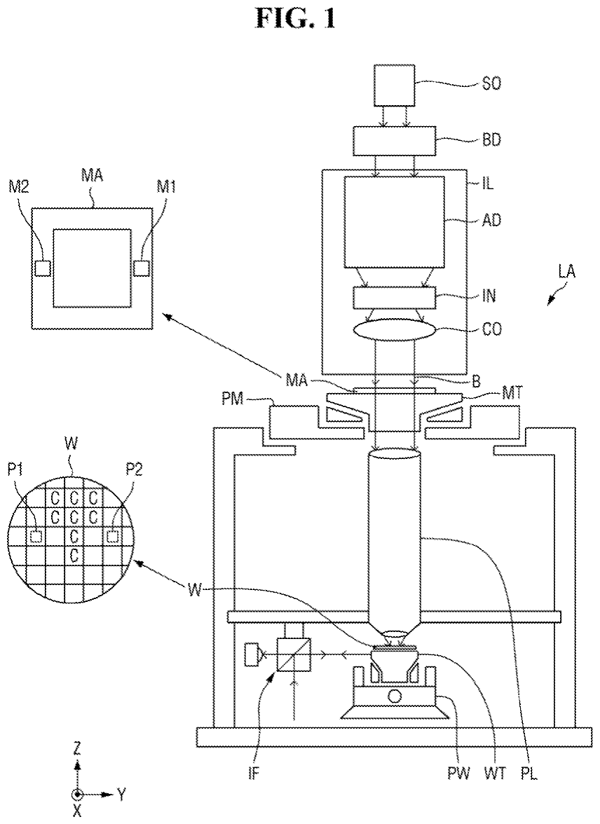

FIG. 1 is a schematic cross-sectional view showing an example embodiment of a lithographic apparatus. A lithographic apparatus LA may include a source SO, an illuminator IL, a patterning device MA, a first positioning device PM, a mask table MT, a second positioning device PW, a wafer table WT, and a projection system PL.

Each of a first direction X and a second direction Y may be substantially parallel to an upper surface of a wafer W inside the lithographic apparatus LA, and the first direction X and the second direction Y may be perpendicular to each other. A third direction Z may be a direction substantially perpendicular to the upper surface of the wafer. In an implementation, the second direction Y may be a direction in which scanning is performed during an exposure process in a scanning scheme.

The source SO may emit a radiation beam B such as, e.g., ultraviolet light, an excimer laser beam, EUV light (extreme ultraviolet light), X-rays or electron beams. The source SO may be a component of the lithographic apparatus LA or may be a separate component therefrom. When the radiation beam B is the excimer laser beam, the source SO may be a separate component from the lithographic apparatus LA. In this case, the radiation beam B may be transferred from the source SO to the illuminator IL by a beam transfer system BD including a beam expander. When the source SO is a mercury lamp, the source SO may be included in the lithographic apparatus LA.

The illuminator IL may receive the radiation beam B from the source SO. The illuminator IL may direct the radiation beam B in a set direction, may shape the radiation beam B and may control the radiation beam. According to some embodiments, the illuminator IL may include optical components belonging to various types such as a refractive type, a reflective type, a magnetic type, an electromagnetic type, or an electrostatic type. The illuminator IL may include an adjuster AD that adjusts an intensity distribution based on an angle of the radiation beam B. The adjuster AD may adjust an outer and/or inner radius of the intensity distribution of a pupil plane of the illuminator IL. The illuminator IL may adjust the radiation beam so that a cross section of the radiation beam B has desired uniformity and intensity distribution. As used herein, the term “or” is not an exclusive term, e.g., “A or B” would include A, B, or A and B.

The mask table MT may support the patterning device MA. The mask table MT may use a mechanical type, vacuum type, or electrostatic type clamping technique or a variety of other clamping techniques to hold the patterning device MA. According to some embodiments, the mask table MT may be a fixed frame or table. According to some other embodiments, the mask table MT may be a movable frame or table. The mask table MT may position the patterning device MA at a position set relative to the projection system PL. The radiation beam B may be incident on the patterning device MA supported by the mask table MT. The cross section of radiation beam B incident on patterning device MA may be changed into a shape set by the patterning device MA. The projection system PL may be a refractive type, a reflective type, a catadioptric type, a magnetic type, an electromagnetic type, or an electrostatic optical type.

According to some embodiments, the patterning device MA may be of a transmissive or reflective type. The patterning device MA may be, e.g., one of a mask, a programmable mirror array, or a programmable LCD panel. When the patterning device MA is of a mask type, the patterning device MA may be a binary type, an alternating phase-shift type, an attenuated phase-shift type, or various hybrid types.

When the patterning device MA is the programmable mirror array, the patterning device MA may include, e.g., a set of small mirrors arranged in a matrix form. Each of the small mirrors included in the patterning device MA may be individually tilted so as to reflect radiation beams incident on the small mirrors in different directions. Each of the small mirrors tilted may form a pattern of the radiation beam B reflected from the mirror matrix.

Subsequently, the radiation beam B may pass through the projection system PL. The projection system PL may focus the radiation beam B onto a target portion C of the wafer W. According to some embodiments, the second positioning device PW and a position sensor IF may move the wafer table WT so that the radiation beam B is sequentially focused on the target portion C of the wafer W on the wafer table WT. Referring to FIG. 1, the lithographic apparatus LA is shown including one wafer table WT and one second positioning device PW. The lithographic apparatus LA may include, a plurality of (e.g., two) wafer tables and a plurality of (e.g., two) second positioning devices. In this case, wafers respectively on different wafer tables may be exposed to light alternately and sequentially.

According to some embodiments, the second positioning device PW may move the wafer table WT to implement a designed circuit pattern. According to some embodiments, the second positioning device PW may move the wafer table WT so that the radiation beam may be focused on a set position on the wafer W. The set position on the wafer may be defined based on a model function calculated using wafer alignment marks P1 and P2. In this regard, the model function may be a function of positions identified based on the wafer alignment marks P1 and P2 or may be a function of a position of any component on the wafer as identified based on the identified positions. The second positioning device PW may move the wafer table WT so that a layer on the wafer W in the lithography process is aligned with an underlying layer to form a semiconductor device that operates normally.

According to some embodiments, a space between the projection system PL and the wafer W may be filled with a liquid having a high refractive index such as water. In some cases, at least a portion of the wafer W may be covered with the liquid. The above liquid may be referred to as an immersion liquid, and the immersion liquid may fill other spaces within the lithographic apparatus, e.g., a space between the patterning device MA and the projection system PL. In this regard, “being immersed” may mean not only that the wafer W is simply submerged in the liquid, but also that the immersion liquid may be placed in a path of the radiation beam B for performing the exposure.

The first positioning device PM and an additional position sensor may accurately move the patterning device MA withdrawn from the mask library and positioned in the path of the radiation beam B during the exposure process.

When the lithographic apparatus LA operates in a step mode, an entire pattern imparted to the radiation beam may be projected onto the target portion C at one time while the mask table MT and the wafer table WT are kept stationary. The patterning device MA and the wafer W may be aligned with each other using mask alignment marks M1 and M2 on the patterning device MA and the wafer alignment marks P1 and P2 on the wafer W. In this regard, the target portion C may be a full shot or a partial shot. Thereafter, the wafer table WT may move in a direction parallel with respect to the upper surface of the wafer W so that another target portion C may be exposed to light. In the step mode, a maximum size of an exposure field may define a size of the target portion C imaged during exposure.

When the lithographic apparatus LA operates in a scan mode, the mask table MT and the wafer table WT may move relative to each other in a synchronized manner while the radiation beam B is projected onto the target portion C. A velocity at and a direction of the motion of the wafer table WT relative to the mask table MT may be determined based on the (de-)magnification and image reversal characteristics of the projection system PL. In the scan mode, the maximum size of the exposure field may limit a horizontal directional width of the target portion C during exposure.

When the patterning device MA is a programmable patterning device including a programmable mirror array and programmable LCD panels, the wafer table WT may be moved or scanned while the mask table MT is kept stationary while the exposure process is performed, such that the radiation beam B may be focused onto the target portion C. In this case, the radiation beam B may be a pulsed source. The patterning device MA may be updated to set a new cross-section of the radiation beam B according to the movement of the wafer table WT.

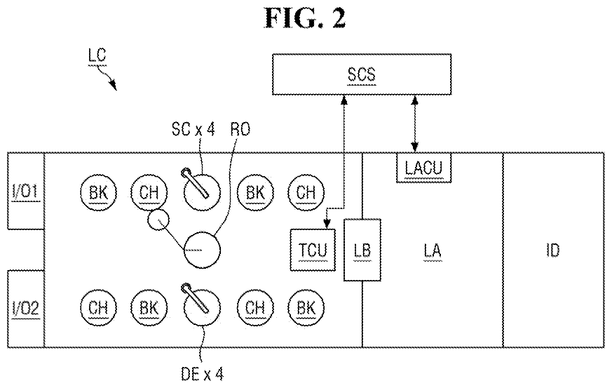

FIG. 2 is a schematic plan view showing an example embodiment of a lithography cell or cluster. Referring to FIG. 2, the lithographic apparatus LA of FIG. 1 may be included in a lithography cell LC. The lithography cell LC may include input/output ports I/O1 and I/O2, a plurality of bake plates BK, a plurality of (e.g., 4) spin coaters SC, a plurality of chill plates CH, a plurality of (e.g., 4) developers DE, a handler robot RO, a track control unit TCU, a loading bay LB, the lithographic apparatus LA, a supervisory control system SCS, a lithography control device LACU, and an inspection device ID.

The lithography cell LC may be a device in which a series of sub-processes constituting a photolithography process are performed. In the lithography cell LC, processes such as adhesion promotion, resist coating, soft bake, alignment, exposure, post-exposure bake, development, wafer inspection, and hard bake may be performed.

The adhesion promotion process may be a process for adhering photoresist to the wafer W or circuit patterns on the wafer W. In some cases, a photoresist material may lack adhesion to a surface of silicon or a silicon-containing material. Therefore, the adhesion promotion process may be performed on the surface of the wafer W before providing the photoresist material on the wafer. A typical adhesion promotion scheme is to treat the wafer surface with hexamethyldisilazane (HMDS). Since the HMDS may convert the wafer surface to be hydrophobic, the adhesion between the photoresist material and the wafer W may be improved.

The spin coater SC may perform a spin coating process. The spin coating process may include applying the photoresist on the wafer W. The photoresist material may be made of an organic polymer applied from a solution. In order to coat the wafer W with the photoresist material, the wafer W on which the photoresist in a solution state has been applied may be spined at high speed. An excessive resist may be removed by the spinning of the wafer W and the solvent evaporates. Thus, a thin solid-state photoresist film may be formed.

A material constituting the photoresist film may be sensitive to any one of UV (Ultra Violet) rays, DUV (Deep UV) rays, EUV (Extreme UV) rays, excimer laser beams, X-rays, and electron beams. The number of photons in an EUV exposure process may be smaller than that in an exposure processes such as a DUV exposure process. Thus, in the EUV exposure process, use of a photoresist material with high EUV absorption may be required. Accordingly, the photoresist material for EUV may include, e.g., hydroxy styrene as a polymer material. Furthermore, iodophenol as an additive may be added to the EUV photoresist.

According to some embodiments, the soft bake process may optionally be performed after the spin coating process. In some cases, a density of the photoresist coated on the wafer may be low such that the subsequent process may not be performed. The soft baking process may densify the photoresist and remove a residual solvent on the photoresist.

The soft bake process may be performed using the bake plate BK. The wafer subjected to the soft bake process may optionally be placed on a chill plate and may be cooled thereon. According to some embodiments, the chill plate CH may include a configured heat dissipation structure to effectively cool a high-temperature wafer on which the bake process has been performed. The bake plate BK may be used to further perform a post-exposure bake process and a hard bake process.

The handler robot RO may pick up wafers from the input/output ports I/O1 and I/O2 and move the wafers between different process devices. The handler robot RO may transfer the wafers on which the process has been performed to the loading bay LB of the lithographic apparatus. The handler robot RO, the input/output ports I/O1 and 1102 and the loading bay LB together may be referred to as a transport track.

The track control unit TCU may control an operation of each of the handler robot RO, the input/output ports I/O1 and I/O2 and the loading bay LB. The track control unit TCU may be controlled by the supervisory control system SCS. The supervisory control system SCS may be controlled by the lithography control device LACU.

The inspection device ID may determine exposure characteristics of each of the wafers, a distribution of the exposure characteristics of different layers of the same wafer, a distribution of the exposure characteristics of different wafers, and/or a distribution of the exposure characteristics of different lots. According to some embodiments, the inspection device ID is shown as being included in the lithography cell LC. In an implementation, the inspection device may be included in the lithographic apparatus LA or may be a device separate from the lithography cell LC and the lithographic apparatus LA.

According to some embodiments, the inspection device ID may include a scattering optical system. When the inspection device ID includes the scattering optical system, the inspection device ID may compare intensities of first scattered light beams from each other and may measure an overlay as a consistency between layers, based on the comparing result. According to some embodiments, the inspection device ID may include an image-based optical system. When the inspection device ID includes the image-based optical system, the inspection device ID may compare a position of an overlay mark on the photoresist pattern with an overlay mark on the underlying layer and may measure the overlay based on the comparing result.

According to some embodiments, the inspection device ID may inspect the photoresist material layer immediately after the exposure. In this regard, a difference between refractive indexes of exposed and non-exposed portions of the photoresist material layer may be very small. Therefore, a latent image of the photoresist material layer before development has very low contrast. According to some embodiments, a post-exposure bake may be performed to increase a contrast between the exposed and non-exposed portions of the photoresist material layer prior to performing the inspection. According to some embodiments, the inspection may be performed after removing the exposed portion or the non-exposed portion of the photoresist material layer. According to some embodiments, a pattern in the photoresist material layer may be transferred to the underlying layer by performing processes such as etching, ashing, and lift-off, and then, the underlying layer may be inspected.

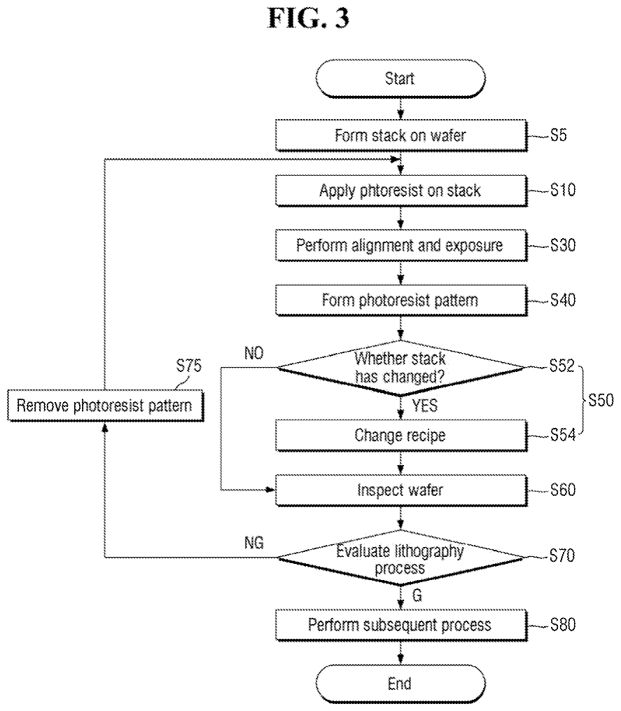

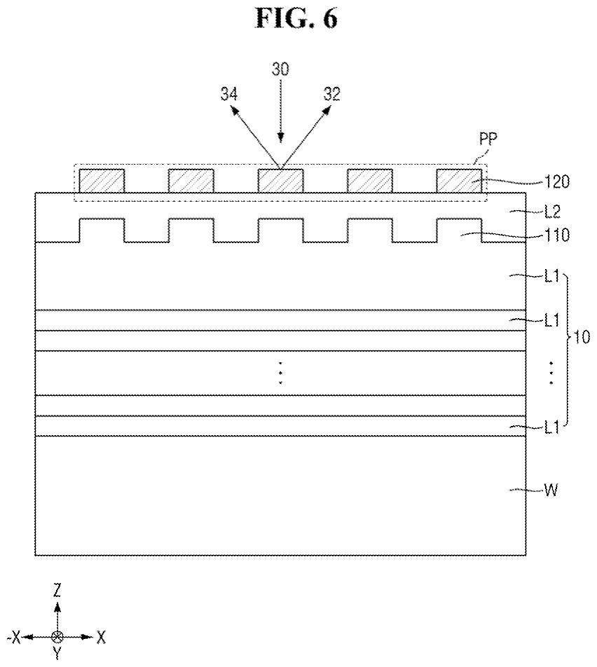

FIG. 3 is a flowchart showing steps in a method for manufacturing a semiconductor device according to example embodiments. Referring to FIG. 1 to FIG. 3, a stack (e.g., 10 in FIG. 6) may be formed on the wafer W in S5. A photoresist may be provided on the stack in S10. Providing the photoresist may include the adhesion promotion process and the spin coating process. S10 may be performed using the lithography cell LC. Subsequently, an alignment process and an exposure process may be performed in S30.

As described above, the patterning device MA and the wafer W may be aligned with each other. The exposure process may be a process that partially changes photoresist properties to provide a photoresist pattern of a set shape. In this regard, the photoresist may be a material that undergoes a photochemical reaction when being exposed to light, and may include positive photoresist and negative photoresist. The positive photoresist may be generally insoluble in a chemical material referred to as a resist development liquid. However, after the positive photoresist is subjected to the exposure process, the positive photoresist may change to be soluble in the resist development liquid. On the contrary, the negative photoresist may be soluble in the resist development solution before the exposure. However, after the negative photoresist is subjected to the exposure process, the negative photoresist may become insoluble in the resist development solution. Selective exposure of the photoresist may be performed using the patterning device MA such as a photo mask. The patterning device MA may be a glass sheet that is partially covered with an opaque material such as chromium, such that the opaque material is removed in an area where a circuit pattern is formed. The light transmitting through the patterning device MA may be projected onto the photoresist, such that a circuit pattern of one layer may be transferred to the photoresist on the wafer W.

After S30 and before S40, the post-exposure bake process may be optionally performed. The post-exposure bake process may be performed using the bake plate BK. The post-exposure bake process may be an optional bake process used to induce additional chemical reactions or diffusion of components within the resist film.

A photoresist pattern may be formed in S40. The photoresist pattern may be formed using the developer DE. The formation of the photoresist pattern is referred to as a development process. The development process refers to a process of removing the exposed or unexposed portion of the photoresist.

Evaluation may be performed in S50. The evaluation may be performed using the inspection device ID. The evaluation S50 may include S52 of determining whether the stack has changed and S54 of changing the recipe upon determination that the stack has changed in S52. When the stack is not formed according to a process condition pre-set in S5 but is formed according to a changed process condition, it may be determined that the stack has changed in S52. When there is a first change in which a material of at least one among the plurality of layers included in the stack changes or a second change in which at least one process among the plurality of processes for forming the stack changes, it may be determined that the stack has changed in S52. When the stack has not changed in S52, S60 may be performed without changing the recipe. When the first change and the second change are absent, it may be determined that the stack has not changed. The evaluation may allow a wafer inspection recipe performed in S60 to be optimized.

The wafer W may be inspected in S60. The inspection may be performed using the inspection device ID. When the stack has changed in S52, the wafer W may be inspected according to the recipe changed in S54. When the stack has not changed in S52, the wafer W may be inspected according to an existing recipe. Various characteristics of the photoresist pattern on the wafer W may be inspected and measured. This inspection may be an ADI (After Development Inspection) process as an inspection process performed after the development process has been performed and before an etching process is performed. The inspection of the wafer W may include measuring the overlay.

The lithography process may be evaluated in S70. The evaluation of the lithography process may include comparing an overlay value with an acceptable critical value.

When, based on a result of the evaluation of the lithography process, the overlay value is lower than or equal to the critical value (G), that is, when the photoresist pattern is formed reliably, a subsequent process may be performed in S80. The subsequent processes may include an etching, ion implantation, or deposition process.

When, based on a result of the evaluation of the lithography process, the overlay value exceeds the critical value (NG), that is, when the photoresist pattern is defective, the subsequent process may not be performed. The photoresist pattern may be removed in S75 and then the process may return to S10, in which the photoresist may be provided again in S10. Then, the alignment and exposure processes may be performed in S30, and the photoresist pattern may be formed in S40. In this regard, the alignment and exposure processes in S30 may depend on a result of inspection performed on the same wafer. Accordingly, the overlay of a lithography process that is re-performed may be improved such that reliability and a yield of the semiconductor device manufacturing process may be improved.

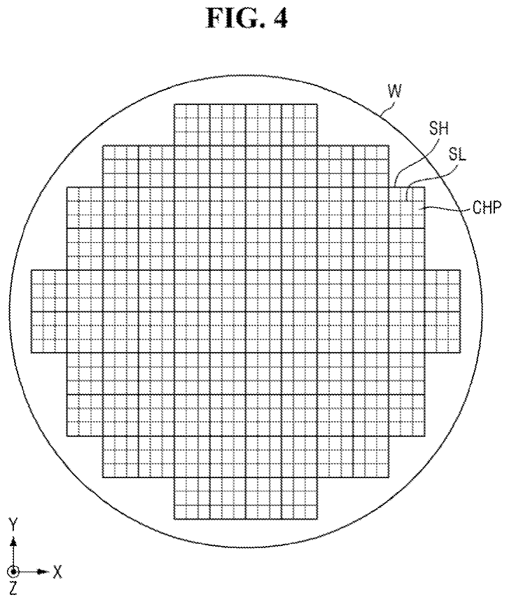

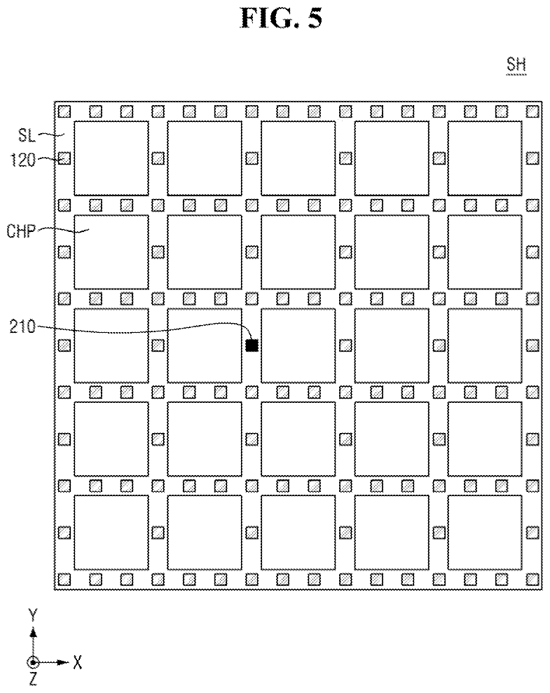

FIG. 4 is a diagram showing a wafer according to example embodiments. FIG. 5 is an enlarged view showing a shot area in FIG. 4. FIG. 6 is a cross-sectional view showing a method for manufacturing a semiconductor according to example embodiments.

Referring to FIGS. 4 and 5, the wafer W may include a plurality of shots SH. The shot SH may be an area exposed to a single exposure process. The shot SH may include one or more chip areas CHP. The chip areas CHP may be isolated from each other or may be defined by a scribe lane area SL. The scribe lane area SL may be a separating line for separating the chip areas CHP into individual semiconductor chips in a sawing process. At least one of a memory element, a logic chip, a measurement element, a communication element, a digital signal processor (DSP) or a SOC (System-On-Chip) may be in the chip area CHP.

In an implementation, an alignment mark 210 and a first overlay mark 110 may be on the scribe lane area SL. In another example, at least one of the alignment mark 130 and the first overlay mark 110 may be in the chip area CHP.

The alignment mark 210 may be a pattern used to accurately define an exposure area of lithography. The alignment mark 210 may be adjacent to the center of the shot SH. In an implementation, each shot SH may include one alignment mark 210. In another example, each of some of the shots SH may include two or more alignment marks 210. In still another example, each of some of the shots SH may not include the alignment mark 210. The alignment mark 210 may include, e.g., the wafer alignment marks P1 and P2 as described with reference to FIG. 2.

The first overlay mark 110 may be a pattern for overlay measurement. The first overlay mark 110 may be a pattern for measuring a consistency between a layer formed in a previous process and a layer formed in a current process. In this regard, the consistency between the layers may include, e.g., an alignment between adjacent layers, and whether circuit defects such as short circuits and open circuits occur. In an implementation, the first overlay marks 110 may be arranged at a higher arrangement density than that at which the alignment marks 130 are arranged.

Referring to FIG. 6, a stack 10 in which a plurality of first layer L1 are stacked may be on the wafer W. A plurality of first layers L1 may be stacked along a third direction Z. The first layer L1 may include the first overlay mark 110. A second layer L2 may be on the stack 10. A photoresist pattern PP may be on the second layer L2. The photoresist pattern PP may include a second overlay mark 120. Each of the first and second overlay marks 110 and 120 may be in a bar pattern or a box pattern.

According to some embodiments, the first layer L1 and the second layer L2 may be optically distinguishable from each other. In an implementation, the first layer L1 may be a conductive layer and the second layer L2 may be an insulating layer. In another example, the first layer L1 may be an insulating layer and the second layer L2 may be a conductive layer. In still another example, the first and second layers L1 and L2 may be respectively insulating layers having different refractive indices or conductive layers having different reflectance. According to some embodiments, each of the first layer L1 and the second layer L2 may have a single layer structure or a multi-layer structure including a plurality of layers. In some cases, the second layer L2 may include a hard mask layer including amorphous carbon.

The recipe as setting information for measuring the overlay may be set based on a process condition for forming the stack 10. The process condition may include, e.g., information about a material of the layer L1, a process of forming the layer L1. When the process condition has changed, measuring the overlay using an existing recipe may have reduced accuracy. Therefore, when the process condition has changed, the recipe needs to be changed. However, there is a limitation in changing the recipe per each process condition.

In particular, the alignment process (S30 in FIG. 3) and the overlay measurement (70 in FIG. 3) may respond sensitively to the first change in which a material of at least one of the plurality of first layers L1 included in the stack 10 has changed, or the second change in which at least one process of the plurality of processes for forming the stack 10 has changed.

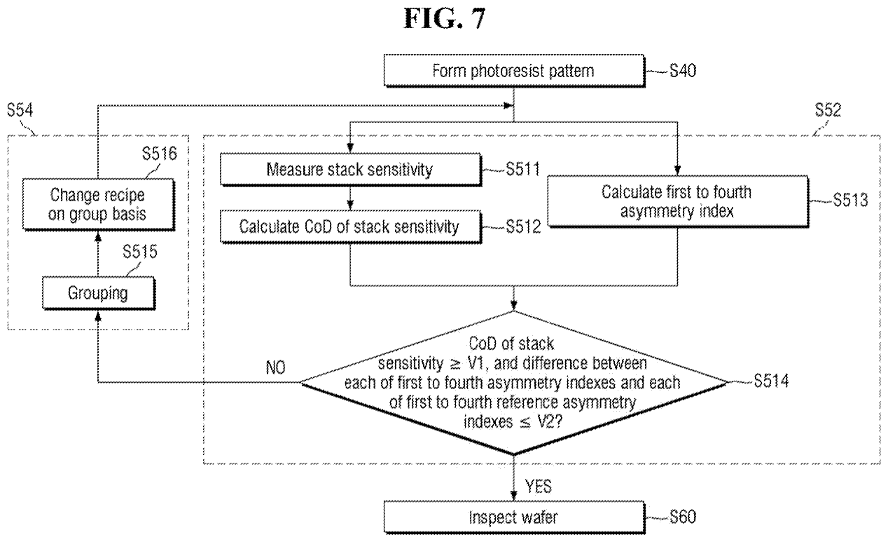

When the first change occurs, performance of detecting the overlay may be affected. when the second change occurs, a profile of the first or second overlay mark 110 or 120 may be affected. Therefore, in a method for manufacturing a semiconductor device according to some embodiments, the first change may be detected based on the overlay detection performance, and the second change may be detected based on the profile of the first or second overlay mark 110 or 120. In the method for manufacturing a semiconductor device according to some embodiments, the recipe may be changed (S54 in FIG. 3) based on a detecting result of the first change and the second change (S52 in FIG. 3). Accordingly, measurement accuracy of the overlay may be improved and/or enhanced. This will be described in detail using FIG. 7 to FIG. 19 below.

FIG. 7 is a flowchart showing steps in a method for manufacturing a semiconductor device according to example embodiments. S52 of FIG. 3 may include S511, S512, S513, and S514 of FIG. 7, and S54 of FIG. 3 may include S515 and S516 of FIG. 7.

In the method for manufacturing a semiconductor device according to some embodiments, the overlay may be measured in a DBO (Diffraction Based Overlay) measurement scheme. In an implementation, the overlay may be measured in the DBO measurement scheme in S60. The first change may be detected using stack sensitivity, and the second change may be detected using first to fourth asymmetry indexes.

Referring to FIG. 6, light 30 may be irradiated to the first overlay mark 110 and the second overlay mark 120, and then, light 30 may be diffracted from the first overlay mark 110 and the second overlay mark 120. Light 30 may be irradiated in a direction perpendicular to the wafer W. A wavelength of light 30 may vary depending on light provided from the inspection device (ID in FIG. 1). Diffracted light beams 32 and 34 may include a + first-order light beam 32 and a − first-order light beam 34. The + first-order light beam 32 may travel in a right direction (an X direction) around the first overlay mark 110 and the second overlay mark 120 and the − first-order light beam 34 may travel in a left direction (a −X direction) around the first overlay mark 110 and the second overlay mark 120. The diffracted light beams 32 and 34 may further include, e.g., 0^{th} order light beam traveling in a direction perpendicular to the upper surface of the wafer W. In the diffraction-based overlay scheme, the overlay may be measured based on the diffracted light beams 32 and 34. When the first change occurs, there may be change in a difference of intensities of the diffracted light beams 32 and 34.

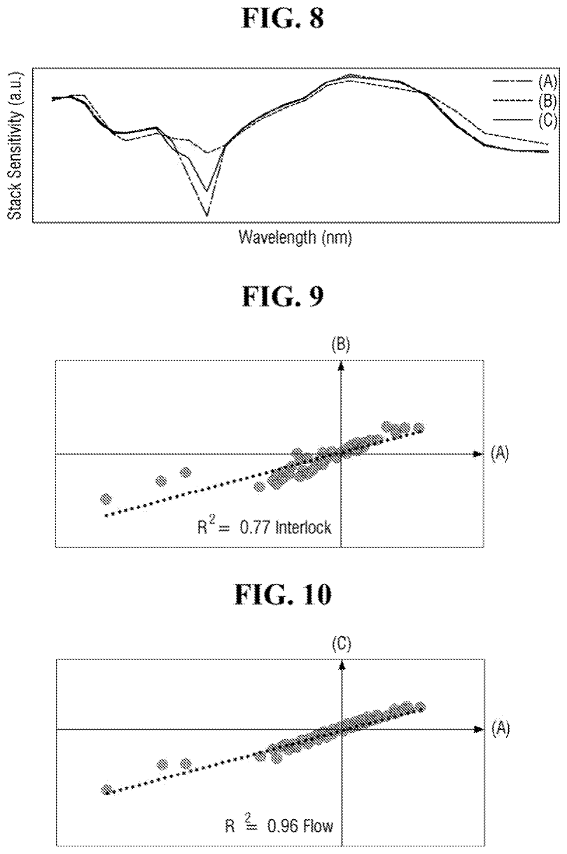

Referring to FIG. 6 and FIG. 7, after S40 has been performed, the stack sensitivity of the stack 10 may be calculated in S511. Referring to FIG. 8, a horizontal axis denotes a wavelength, and a vertical axis denotes the stack sensitivity indicated in any unit. (A) indicates a wavelength-based stack sensitivity when the stack 10 is formed under a reference process condition. Each of (B) and (C) indicates the stack sensitivity measured in S511 after S5. The stack sensitivity may be based on a difference between intensities of diffracted light beams 32 and 34. The stack sensitivity may be based on the difference between the intensities of the + first-order light beam 32 and the − first-order light beam 34. The stack sensitivity may be obtained based on a wavelength of the light 30. The stack sensitivity may be obtained based on a wavelength of light irradiated from the inspection device (ID in FIG. 1).

Subsequently, a CoD (Coefficient of Determination) R² of the stack sensitivity may be calculated in S512. Referring to FIG. 9 and FIG. 10, the CoD (Coefficient of Determination) R² may be calculated based on a comparing result between the stack sensitivity (A) in the reference process condition and the stack sensitivity (B) and (C) measured in S511, based on a wavelength.

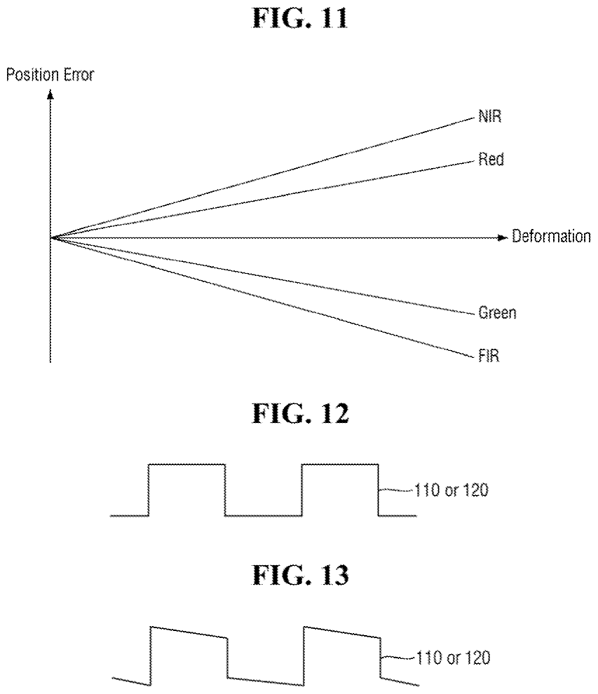

In one example, FIG. 11 shows a position error based on a deformation amount of the first or second overlay mark 110 or 120 based on a wavelength. FIG. 12 shows a profile of the first or second overlay mark without deformation, and FIG. 13 shows a profile of the first or second overlay mark with deformation. In FIG. 11, the position error based on the deformation is measured using NIR (Near infrared), FIR (Far infrared), green light Green, and red light Red by way of example.

Referring to FIG. 11 to FIG. 13, the larger the deformation amount of the first or second overlay mark 110 or 120, the larger the position error. In an implementation, the first or second overlay mark 110 or 120 may be deformed such that heights of opposite sidewalls thereof may be different from each other. Accordingly, the first or second overlay mark 110 or 120 may have an asymmetric structure. This may have an asymmetrical effect on the diffraction of the light, and thus the position error may occur. The position error may be based on a difference between the intensities of the + first-order light beam 32 and the − first-order light beam 34. The position error may be, e.g., a value obtained by subtracting the intensity of the − first-order light beam 34 from the intensity of the + first-order light beam 32. The asymmetry index may be a normalized value of the position error.

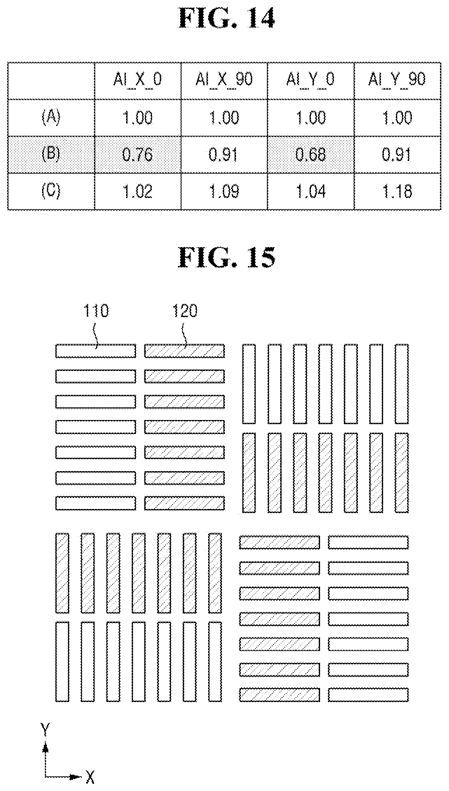

Referring to FIG. 7 and FIG. 14, the first to fourth asymmetry indexes may be calculated in S513. The first or second overlay mark 110 or 120 may include a first mark for measuring the overlay in the first direction X and a second mark for measuring the overlay in the second direction Y. An asymmetry index AI_X_0 related to the first mark and an asymmetry index AI_Y_0 related to the second mark may be calculated using light. An asymmetry index AI_Y_0 related to the first mark and an asymmetry index AI_Y_90 related to the second mark may be calculated using 90 degrees polarization of the light. The light may have one wavelength or may have a plurality of wavelengths. (A) indicates the first to fourth reference indexes AI_X_0. AI_X_90. AI_Y_0, and AI_Y_90 when the stack 10 is formed in the reference process condition. Each of (B) and (C) indicates the first to fourth indexes AI_X_0, AI_X_90, AI_Y_0, and AI_Y_90 as calculated in S513 after S5.

Then, it may be determined whether the CoD (Coefficient of Determination) R² of the stack sensitivity is greater than or equal to a first critical value V1, and a difference between each of the first to fourth asymmetry indexes and each of the first to fourth reference asymmetry indexes is equal to or smaller than a second critical value V2 in S514. When the CoD (Coefficient of Determination) R² of the stack sensitivity is greater than or equal to the first critical value V1, and the difference between each of the first to fourth asymmetry indexes and each of the first to fourth reference asymmetry indexes is smaller than or equal to the second critical value V2, S70 may be performed. When the CoD (Coefficient of Determination) R² of the stack sensitivity is smaller than the first critical value V1 or the difference between each of the first to fourth asymmetry indexes and each of the first to fourth reference asymmetry indexes exceeds the second critical value V2, S515 may be performed.

In an implementation, referring to FIG. 9, FIG. 10 and FIG. 14, it may be assumed that the first critical value V1 is 0.8 and the second critical value V2 is 0.2. In this case, regarding (B), the CoD (Coefficient of Determination) R² of the stack sensitivity may be 0.77 which may be smaller than the first critical value V1, and the difference between the first asymmetry index 0.76 and the first reference asymmetry index 1 may be 0.24 which may exceed the second critical value V2. The difference between the second asymmetry index 0.68 and the second reference asymmetry index 1 may be 0.32 and thus may exceed the second critical value V2. Thus, S515 may be performed. In regarding (C), the CoD (Coefficient of Determination) R² of the stack sensitivity is 0.96 which may be greater than the first critical value V1. The differences between the first to fourth asymmetry indexes 1, 1, 1, and 1 and the first to fourth reference asymmetry indexes 1.02, 1.09, 1.04, and 1.18, respectively are 0.02, 0.09, 0.04, and 0.18, respectively, which may be smaller than the second critical value V2. Thus, S60 may be performed.

Referring back to FIG. 7, grouping may be performed in S515. The grouping may be performed, e.g., based on at least one of the CoD (Coefficient of Determination) R₂ of the stack sensitivity and the first to fourth asymmetry indexes. The grouping may be performed based on the difference between each of the first to fourth reference asymmetry indexes and the first to fourth asymmetry indexes. In an implementation, the grouping may be performed based on the stack sensitivity.

In an implementation, the grouping may be performed based on the CoD (Coefficient of Determination) R² of the stack sensitivity. According to some embodiments, S50 may be performed lot by lot. The lot may include a plurality of wafers. In an implementation, the grouping may be performed on a lot basis. S511 to S514 may be performed on each of wafers, and then, wafers that do not satisfy S514 may be grouped based on the CoD (Coefficient of Determination) R² of the stack sensitivity thereof. According to some embodiments, S50 may be performed periodically. In an implementation, the grouping may be performed on each of wafers provided for a certain period of time. S511 to S514 may be performed on each of wafers provided for a certain period of time, and then, wafers that do not satisfy S514 may be grouped based on the CoD (Coefficient of Determination) R² of the stack sensitivity thereof. In an implementation, wafers having similar CoDs (Coefficient of Determination) R² of the stack sensitivity may be grouped into a single group.

Subsequently, the recipe may be changed based on each group determined in S515 in S516. The recipe may be optimized based on each group. In an implementation, the recipe may include information on the wavelength for overlay measurement used in S60, and the wavelength for overlay measurement may be changed in S516. In an implementation, the recipe may be optimized in S516. Therefore, the overlay may be measured using the wavelength for overlay measurement optimized in S516 for inspecting the wafer in S60, and thus, reliability or accuracy of overlay measurement may be improved.

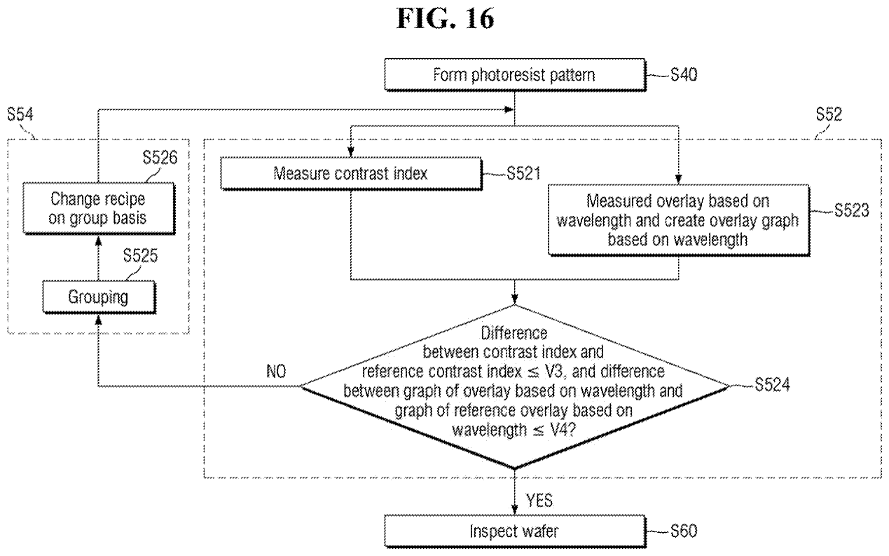

FIG. 15 is a diagram showing first and second overlay marks of FIG. 6. FIG. 16 is a flowchart showing steps in a method for manufacturing a semiconductor device according to example embodiments.

In the method for manufacturing a semiconductor device according to some embodiments, the overlay may be measured in an IBO (Image Based Overlay) measurement scheme. In an implementation, the overlay may be measured in the IBO measurement scheme in S60. The first change may be detected using a contrast index and the second change may be detected using a wavelength-based overlay.

Referring to FIG. 6 and FIG. 15, the photoresist pattern PP including the second overlay mark 120 may be formed and then, images of the first overlay mark 110 of the stack 10 and the second overlay mark 120 of the photoresist pattern PP may be acquired together. This scheme may measure the overlay based on a comparing result between a position of the first overlay mark 110 and a position of the second overlay mark 120.

Referring to FIG. 15 and FIG. 16, after S40, the contrast index may be calculated in S521. The contrast index may mean how accurately an image contrast based on a wavelength can be recognized. The contrast index may mean an accuracy at which a boundary of the first or second overlay mark 110 or 120 is recognized.

The overlay may be measured based on a wavelength and an overlay graph based on the wavelength may be created in S523. At this time, the overlay may be measured in the IBO measurement scheme.

Subsequently, it may be determined whether a difference between the contrast index and a reference contrast index is smaller than or equal to a third critical value V3 and whether a difference between the overlay graph based on the wavelength and a reference overlay graph based on the wavelength is smaller than or equal to a fourth critical value V4 in S524. The contrast index may be compared with the reference contrast index when the stack 10 is formed under reference process condition. The overlay graph may be compared with the reference overlay graph based on the wavelength when the stack 10 is formed under the reference process condition. In an implementation, a slope of the overlay graph may be compared with a slope of the reference overlay graph. Thus, it may be determined whether a difference between the slope of the overlay graph and the slope of the reference overlay graph is equal to or smaller than the fourth critical value V4. In another example, a shape of the overlay graph and a shape of the reference overlay graph may be compared with each other, and thus, it may be determined whether a difference between the shape of the overlay graph and the shape of the reference overlay graph is equal to or smaller than the fourth critical value V4.

When the difference between the contrast index and the reference contrast index is smaller than or equal to the third critical value V3 and the difference between the overlay graph based on the wavelength and the reference overlay graph based on the wavelength is smaller than or equal to the fourth critical value V4, S60 may be performed.

When the difference between the contrast index and the reference contrast index exceeds the third critical value V3, or when the difference between the overlay graph based on the wavelength and the reference overlay graph based on the wavelength exceeds the fourth critical value V4, grouping may be performed in S525. The grouping may be performed, e.g., based on at least one of the contrast index and the overlay graph. The grouping may be performed, e.g., based on the difference between the contrast index and the reference contrast index. The grouping may be performed based on the difference between the overlay graph and the reference overlay graph.

Subsequently, the recipe may be changed based on each of groups determined in S525 in S526. In an implementation, the recipe may include information on the wavelength for overlay measurement used in S523, and the wavelength for overlay measurement may be changed in S526. In an implementation, the recipe may be optimized in S526. Therefore, the overlay may be measured using the wavelength for overlay measurement as optimized in S526 for inspecting the wafer in S60, and thus reliability or accuracy of the overlay measurement may be improved.

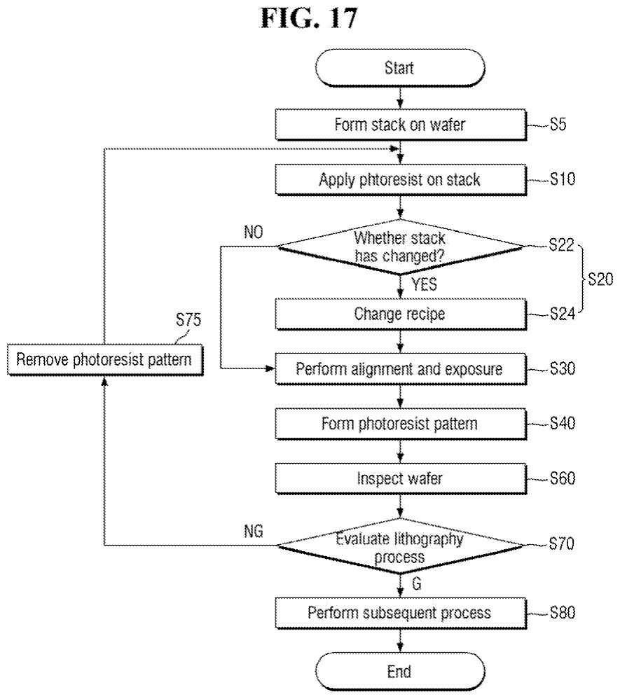

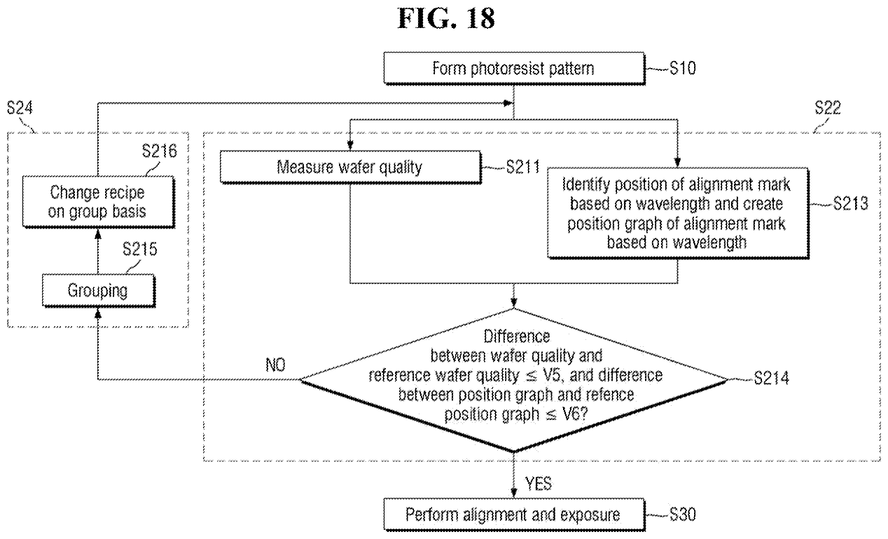

FIG. 17 is a flowchart showing steps in a method for manufacturing a semiconductor device according to example embodiments. FIG. 18 is a flowchart showing steps included in S20 in FIG. 17. For convenience of description, differences thereof from those as set forth above with reference to FIG. 1 to FIG. 16 will be set forth.

Referring to FIG. 17, the photoresist may be applied on the wafer in S10, and then the evaluation may be performed in S20. After the evaluation is performed, the alignment and exposure processes may be performed in S30. The evaluation may be performed using the inspection device (ID in FIG. 1). The wafer alignment recipe performed in S30 may be optimized based on the evaluation result.

In the method for manufacturing a semiconductor device according to some embodiments, the first change may be detected using a wafer quality and the second change may be detected using a position of an alignment mark per each wavelength.

Referring to FIG. 5 and FIG. 18, the wafer quality may be calculated in S211. The wafer quality may mean an intensity of the diffracted light diffracted from the alignment mark 130.

The method may identify the position of the alignment mark 130 per each wavelength and create a position graph of the alignment mark based on the wavelength in S213.

Subsequently, it may be determined whether a difference between the wafer quality and a reference wafer quality is smaller than or equal to a fifth critical value V5 and whether a difference between a position graph of the alignment mark based on the wavelength and a reference position graph of the alignment mark based on the wavelength is smaller than or equal to a sixth critical value V6 in S214. The wafer quality may be compared with the reference wafer quality when the stack 10 is formed under the reference process condition. The position graph of the alignment mark based on the wavelength and the reference position graph thereof may be compared with each other. In an implementation, a slope of the position graph may be compared with a slope of the reference position graph, and thus it may be determined whether a difference between the slope of the position graph and the slope of the reference position graph is equal to or smaller than the fifth critical value V5. In another example, a shape of the position graph may be compared with a shape of the reference position graph, and thus it may be determined whether a difference between the shape of the position graph and the shape of the reference position graph is equal to or smaller than the sixth critical value V6.

When the difference between the wafer quality and the reference wafer quality is smaller than or equal to the fifth critical value V5, and the difference between the position graph and the reference position graph is smaller than or equal to the sixth critical value V6, S30 may be performed. When the difference between the wafer quality and the reference wafer quality exceeds the fifth critical value V5 or the difference between the position graph and the reference position graph exceeds the sixth critical value V6, grouping may be performed in S215. The grouping may be performed based on at least one of the wafer quality and the position graph, e.g. The grouping may be performed based on the difference between the wafer quality and the reference wafer quality. The grouping may be performed based on the difference between the position graph and the reference position graph.

Subsequently, the recipe may be changed based on each of groups determined in S215 in S216. In an implementation, the recipe may include information on the wavelength for alignment used in S30, and the wavelength for alignment may be changed in S216. In an implementation, the alignment recipe may be optimized in S216. Accordingly, alignment may be performed using the optimized wavelength from S216 to perform alignment and exposure in S30. The wavelength for alignment may be referred to as a measurement wavelength.

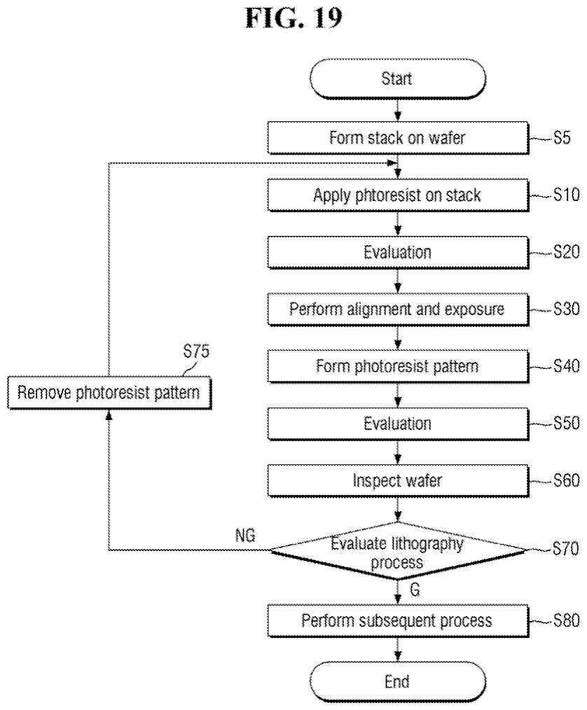

FIG. 19 is a flowchart showing steps in a method for manufacturing a semiconductor device according to example embodiments. For convenience of description, differences thereof from those as set forth above with reference to FIG. 1 to FIG. 18 will be set forth.

Referring to FIG. 19, in the method for manufacturing a semiconductor device according to some embodiments, the evaluation S20 may be performed before the alignment and exposure processes S30, and evaluation S50 may be performed before the wafer inspection S60. The evaluation S20 may be the evaluation S20 of FIG. 17 and FIG. 18, and the evaluation S50 may be the evaluation S50 of FIG. 7 or the evaluation S50 of FIG. 16.

By way of summation and review, the semiconductor processes may include, e.g., a deposition process of depositing a material film on a wafer, a photolithography process for defining a pattern on the wafer, an etching process of etching a material layer of the wafer, a process of implanting impurities into the wafer. These semiconductor processes may be performed such that a semiconductor device may be formed according to a designed layout. Various schemes are being studied to determine a performance state of and presence or absence of defects in each of the semiconductor processes and after performing the semiconductor processes. Among the schemes, high-reliability and high-precision overlay measurement is one of the key factors to achieve a high product yield in semiconductor device manufacturing. As the semiconductor device is miniaturized and highly integrated, various studies are being conducted to improve accuracy and reliability of the overlay measurement.

A technical purpose to be achieved by the present disclosure is to provide a method for manufacturing a semiconductor device that can optimize an overlay recipe to improve reliability or accuracy of overlay measurement.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method for manufacturing a semiconductor device, the method comprising:
forming a stack on a wafer, wherein the stack includes a plurality of layers of the stack;
forming a photoresist pattern on the stack;
determining whether a material of at least one layer among the plurality of layers of the stack has changed and whether at least one process among a plurality of processes for forming the plurality of layers of the stack has changed;
changing a first wavelength for overlay measurement upon determination that the material of the at least one layer or the at least one process has changed; and
measuring an overlay using the changed first wavelength for overlay measurement.

2. The method as claimed in claim 1, wherein:
the stack includes a first overlay mark,
the photoresist pattern includes a second overlay mark, and
determining whether the material of the at least one layer has changed includes:
acquiring a stack sensitivity based on a second wavelength, the stack sensitivity being based on a difference between intensities of diffracted light beams, and light irradiated to the first and second overlay marks being diffracted from the first and second overlay marks such that the diffracted light beams are generated;
comparing the stack sensitivity and a reference stack sensitivity with each other to obtain a Coefficient of Determination; and
determining, when the Coefficient of Determination is greater than or equal to a critical value, that the material of the at least one layer has changed.

3. The method as claimed in claim 2, wherein:
forming the stack, forming the photoresist pattern, and determining whether the material of the at least one layer has changed and whether the at least one process has changed are performed on each of wafers of a lot, and
changing the first wavelength for overlay measurement includes:
grouping each of the wafers of the lot, based on the stack sensitivity of each of the wafers of the lot; and
changing the first wavelength for overlay measurement on a group basis.

4. The method as claimed in claim 2, wherein:
forming the stack, forming the photoresist pattern, and determining whether the material of the at least one layer has changed, and whether the at least one process has changed are performed on each of the wafers provided for a predefined period of time, and
changing the first wavelength for overlay measurement includes:
grouping each of the wafers provided for the predefined period of time, based on the stack sensitivity of each of the wafers; and
changing the first wavelength for overlay measurement based on a group basis.

5. The method as claimed in claim 1, wherein:
the stack includes a first overlay mark,
the photoresist pattern includes a second overlay mark, and
determining whether the at least one process has changed includes:
acquiring a difference between intensities of diffracted light beams, and light irradiated to the first and second overlay marks being diffracted from the first and second overlay marks such that the diffracted light beams are generated; and
determining whether the at least one process has changed, based on the difference between the intensities of the diffracted light beams.

6. The method as claimed in claim 5, wherein the light includes a first light and a second light having different wavelengths.

7. The method as claimed in claim 5, wherein:
each of the first and second overlay marks includes a first mark for measuring an overlay in a first direction and a second mark for measuring an overlay in a second direction, and
determining whether the at least one process has changed includes:
acquiring a first difference between intensities of diffracted light beams, and first light irradiated to the first mark being diffracted from the first mark such that the diffracted light beams are generated;
acquiring a second difference between intensities of diffracted light beams, wherein the first light irradiated to the second mark is diffracted from the second mark such that the diffracted light beams are generated;
comparing the first intensity difference with a first reference intensity difference, and comparing the second intensity difference with a second reference intensity difference; and
determining whether the at least one process has changed, based on the comparing results.

8. The method as claimed in claim 7, wherein:
determining whether the at least one process has changed further includes:
acquiring a third difference between intensities of diffracted light beams, second light irradiated to the first mark being diffracted from the first mark such that the diffracted light beams are generated;
acquiring a fourth difference between intensities of diffracted light beams, the second light irradiated to the second mark being diffracted from the second mark such that the diffracted light beams are generated;
comparing the third intensity difference with a third reference intensity difference, and comparing the fourth intensity difference with a fourth reference intensity difference; and
determining whether the at least one process has changed, based on the comparing results, the second light being polarized light of the first light.

9. The method as claimed in claim 1, wherein:
the stack includes a first overlay mark,
the photoresist pattern includes a second overlay mark,
determining whether the at least one process has changed includes:
acquiring an image contrast of each of the first overlay mark and the second overlay mark, based on a third wavelength;
comparing the image contrast with a reference image contrast and acquiring a Coefficient of Determination based on the comparing result; and
determining, when the Coefficient of Determination is greater than or equal to a critical value, that the at least one process has changed.

10. The method as claimed in claim 1, wherein:
the stack includes a first overlay mark,
the photoresist pattern includes a second overlay mark, and
determining whether the material of the at least one layer has changed includes:
measuring an overlay based on a second wavelength;
creating a graph of the overlay based on the second wavelength;
comparing the graph and a reference graph with each other; and
determining whether the material of the at least one layer has changed, based on the comparing result.

11. A method for manufacturing a semiconductor device, the method comprising:
forming a stack on a wafer, wherein the stack includes a plurality of layers of the stack;
forming a photoresist pattern on the stack;
determining whether a material of at least one layer among the plurality of layers of the stack has changed and whether at least one process among a plurality of processes for forming the plurality of layers of the stack has changed;
changing a first wavelength for alignment upon determination that the material of the at least one layer or the at least one process has changed;
aligning the wafer using the changed first wavelength for alignment; and
developing the photoresist pattern to generate a developed photoresist pattern.

12. The method as claimed in claim 11, wherein:
the stack includes an alignment mark, and
determining whether the material of the at least one layer has changed includes:
acquiring a wafer quality, based on a second wavelength, the wafer quality being based on a difference between intensities of diffracted light beams, light irradiated to the alignment mark being diffracted from the alignment mark such that the diffracted light beams are generated;
comparing the wafer quality and a reference wafer quality with each other; and
determining whether the material of the at least one layer has changed, based on the comparing result.

13. The method as claimed in claim 12, wherein:
forming the stack, forming the photoresist pattern, and determining whether the material of the at least one layer has changed and whether the at least one process has changed are performed on each of wafers of a lot, and
changing the first wavelength for alignment includes:
grouping each of the wafers of the lot, based on the wafer quality of each of the wafers of the lot; and
changing the first wavelength for alignment on a group basis.

14. The method as claimed in claim 12, wherein:
forming the stack, forming the photoresist pattern, and determining whether the material of the at least one layer has changed, and whether the at least one process has changed are performed on each of the wafers provided for a predefined period of time, and
changing the first wavelength for alignment includes:
grouping each of the wafers provided for the predefined period of time, based on the wafer quality of each of the wafers; and
changing the first wavelength for alignment based on a group basis.

15. The method as claimed in claim 11, wherein:
the stack includes an alignment mark, and
determining whether the material of the at least one layer has changed includes:
identifying a position of the alignment mark based on a second wavelength;
generating a graph of the position of the alignment mark based on the second wavelength;
comparing the graph and a reference graph with each other; and
determining whether the material of the at least one layer has changed, based on the comparing result.

16. A method for manufacturing a semiconductor device, the method comprising:
forming a stack on a wafer, wherein the stack includes a plurality of layers of the stack;
forming a photoresist pattern on the stack;
aligning the wafer, and then developing the photoresist pattern to generate a developed photoresist pattern;
determining whether a material of at least one layer of the plurality of layers of the stack has changed and whether at least one process among a plurality of process for forming the plurality of layers of the stack has changed;
changing a measurement wavelength upon determination that the material of the at least one layer or the at least one process has changed; and
aligning the wafer and/or measuring an overlay of the developed photoresist pattern using the changed measurement wavelength.

17. The method as claimed in claim 16, wherein:
forming the stack, forming the photoresist pattern, and determining whether the material of the at least one layer has changed and whether the at least one process has changed are performed on each of wafers of a lot, and
changing the measurement wavelength includes:
grouping each of the wafers of the lot; and
changing the measurement wavelength on a group basis.

18. The method as claimed in claim 16, wherein:
forming the stack, forming the photoresist pattern, and determining whether the material of the at least one layer has changed, and whether the at least one process has changed are performed on each of the wafers provided for a predefined period of time, and
changing the measurement wavelength includes:
grouping each of the wafers provided for the predefined period of time; and
changing the measurement wavelength on a group basis.

19. The method as claimed in claim 16, further comprising determining whether the overlay is greater than or equal to a critical value.

20. The method as claimed in claim 19, further comprising:
removing the developed photoresist pattern upon determination that the overlay is equal to or greater than the critical value; and
etching the stack using the developed photoresist pattern upon determination that the overlay is smaller than the critical value.
